(19) United States
(12) Patent Application Publication
(10) Pub. No.: US 2024/0429052 A1
(43) Pub. Date: Dec. 26, 2024

(54) METHOD OF MANUFACTURING SEMICONDUCTOR DEVICE

(71) Applicant: SAMSUNG ELECTRONICS CO., LTD., SUWON-SI (KR)

(72) Inventors: Sangjun PARK, Suwon-si (KR); Bongcheol KIM, Suwon-si (KR); Sangho LEE, Suwon-si (KR); Yeongeun YOOK, Suwon-si (KR)

(21) Appl. No.: 18/660,507

(22) Filed: May 10, 2024

(30) Foreign Application Priority Data
Jun. 21, 2023 (KR) 10-2023-0079933

(51) Int. Cl. H01L 21/027; H01L 21/308; H01L 21/311

(52) U.S. Cl. CPC H01L 21/0274; H01L 21/3086; H01L 21/31144

(57) ABSTRACT

A method of manufacturing a semiconductor device includes sequentially forming an etch target film and an insulating film on a substrate. A first photoresist film is formed on the insulating film. A first photoresist pattern is formed exposing a first region of the insulating film by patterning the first photoresist film. A protective film is formed covering the first photoresist pattern and the first region of the insulating film. A second photoresist pattern is formed exposing a second region of the protective film. The protective film covers the first photoresist pattern during the forming of the second photoresist pattern. A first trench is formed by etching the etch target film using the first photoresist pattern. A second trench is formed by etching the etch target film using the second photoresist pattern. The forming of the first trench is performed after the forming of the second photoresist pattern.

### CROSS-REFERENCE TO RELATED APPLICATION

This application claims priority under 35 U.S.C. § 119 to Korean Patent Application No. 10-2023-0079933, filed on Jun. 21, 2023 in the Korean Intellectual Property Office, the disclosure of which is incorporated by reference in its entirety herein.

### 1. Technical Field

The present inventive concept relates to a method of manufacturing a semiconductor device.

### 2. Discussion of Related Art

Electronic devices are becoming increasingly compact and lightweight along with the rapid development of the electronics industry. Accordingly, there is an increased demand for semiconductor devices having a high degree of integration for use in electronic devices. Thus, design rules for configurations of semiconductor devices are being reduced.

### SUMMARY

Embodiments of the present disclosure provide a method of manufacturing a semiconductor device having reduced processes.

The problems to be solved by embodiments of the present disclosure are not limited to the problems mentioned above, and other problems not mentioned will be clearly understood by those skilled in the art from the description below.

According to an embodiment of the present disclosure, a method of manufacturing a semiconductor device includes sequentially forming an etch target film and an insulating film on a substrate. A first photoresist film is formed on the insulating film. A first photoresist pattern is formed exposing a first region of the insulating film by patterning the first photoresist film. A protective film is formed covering the first photoresist pattern and the first region of the insulating film. A second photoresist pattern is formed exposing a second region of the protective film. The protective film covers the first photoresist pattern during the forming of the second photoresist pattern. A first trench is formed by etching the etch target film using the first photoresist pattern. A second trench is formed by etching the etch target film using the second photoresist pattern. The forming of the first trench is performed after the forming of the second photoresist pattern.

According to an embodiment of the present disclosure, a method of manufacturing a semiconductor device includes sequentially forming an etch target film, a hard mask film, and an insulating film on a substrate. A first photoresist film is formed on the insulating film. A first photoresist pattern is formed exposing a first region of the insulating film by patterning the first photoresist film. A protective film is formed covering the first photoresist pattern and the first region of the insulating film. A second photoresist pattern is formed exposing a second region of the protective film. The protective film covers the first photoresist pattern during the forming of the second photoresist pattern. A first trench is formed by etching the etch target film using the first photoresist pattern. A second trench is formed by etching the etch target film using the second photoresist pattern. In the forming of the second photoresist pattern, the second photoresist pattern is spaced apart from the first photoresist pattern with the protective film disposed therebetween.

According to an embodiment of the present disclosure, a method of manufacturing a semiconductor device includes sequentially forming an etch target film, a hard mask film, and an insulating film on a substrate. A first photoresist film is formed on the insulating film. A first photoresist pattern is formed exposing a first region of the insulating film by patterning the first photoresist film. An oxide film is formed covering the first photoresist pattern and the first region of the insulating film. A second photoresist pattern is formed exposing a second region of the oxide film. The oxide film covers the first photoresist pattern during the forming of the second photoresist pattern. An oxide film pattern is formed by etching the second region of the oxide film using the second photoresist pattern. A first middle trench is formed by etching the first region of the insulating film using the first photoresist pattern. A third photoresist pattern is formed by etching a portion of the first photoresist pattern exposed by the oxide film pattern. A second middle trench is formed having a depth less than a depth of the first middle trench by etching a second region of the insulating film using the third photoresist pattern. A hard mask pattern is formed by etching a portion of the hard mask film exposed by the first middle trench of the insulating film. A via trench is formed by etching a portion of the etch target film exposed by the hard mask pattern. A line trench is formed by etching portions of the insulating film, the hard mask pattern, and the etch target film that overlap a lower surface of the second middle trench. The via trench overlaps the line trench. The forming of the via trench is performed after the forming of the second photoresist pattern.

### BRIEF DESCRIPTION OF THE DRAWINGS

Embodiments will be more clearly understood from the following detailed description taken in conjunction with the accompanying drawings in which:

FIG. 1 is a flowchart illustrating a method of manufacturing a semiconductor device, according to an embodiment of the present disclosure;

FIGS. 2 to 16 are cross-sectional views illustrating a method of manufacturing a semiconductor device, according to embodiments of the present disclosure; and

FIGS. 17 to 19 are flowcharts illustrating a method of manufacturing a semiconductor device, according to embodiments of the present disclosure.

### DETAILED DESCRIPTION OF EMBODIMENTS

Hereinafter, embodiments of the present inventive concept will be described in detail with reference to the accompanying drawings. Like reference numerals are used for like components in the drawings, and duplicate descriptions thereof are omitted.

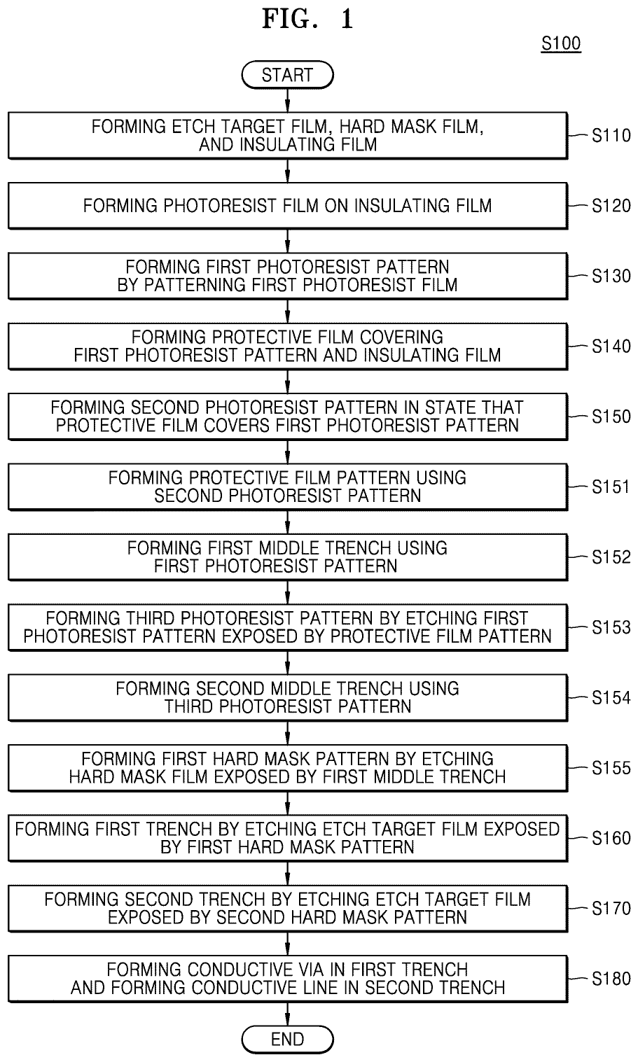

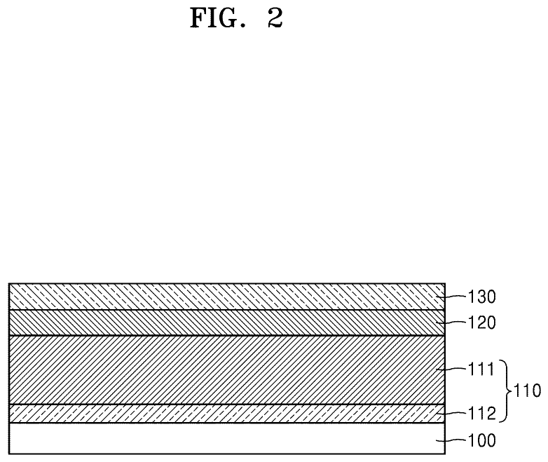

FIG. 1 is a flowchart illustrating a method of manufacturing a semiconductor device, according to an embodiment. Specifically, FIG. 1 is a flowchart illustrating a method (S100) of manufacturing a semiconductor device. FIGS. 2 to 16 are cross-sectional views illustrating the method (S100) of manufacturing a semiconductor device according to embodiments.

Referring to FIGS. 1 and 2 together, an operation of forming an etch target film 110, a hard mask film 120, and an insulating film 130 may be performed in block S110.

As illustrated in FIG. 2, the etch target film 110, the hard mask film 120, and the insulating film 130 may be sequentially formed on a substrate 100. In an embodiment, the etch target film 110 may include a first etch target film 111 and a second etch target film 112. In some embodiments, the first etch target film 111 may include an oxide. For example, the first etch target film 111 may include silicon oxide. In some embodiments, the second etch target film 112 may include silicon nitride. In some embodiments, the hard mask film 120 may include a spin-on hard mask (SOH) film. In some embodiments, the insulating film 130 may include silicon oxynitride.

In some embodiments, the second etch target film 112 may be formed on (e.g., formed directly thereon) the substrate 100, the first etch target film 111 may be formed on the second etch target film 112, and the hard mask film 120 may be formed on (e.g., formed directly thereon) the first etch target film 111. In some embodiments, the hard mask film 120 may directly contact the first etch target film 111. However, embodiments of the present disclosure are not necessarily limited thereto. The insulating film 130 may be formed on (e.g., formed directly thereon) the hard mask film 120.

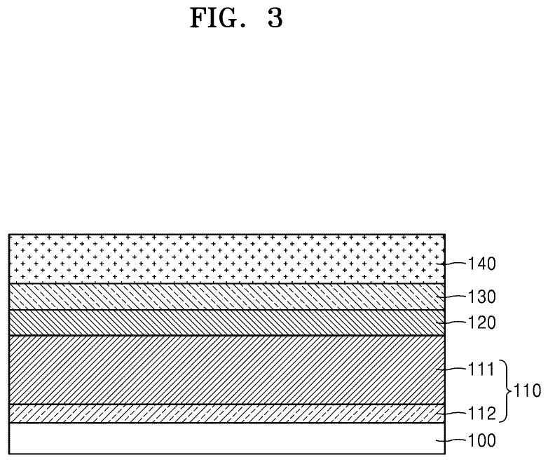

Referring to FIGS. 1 and 3 together, an operation of forming a first photoresist film 140 on the insulating film 130 (e.g., formed directly thereon) may be performed in block S120.

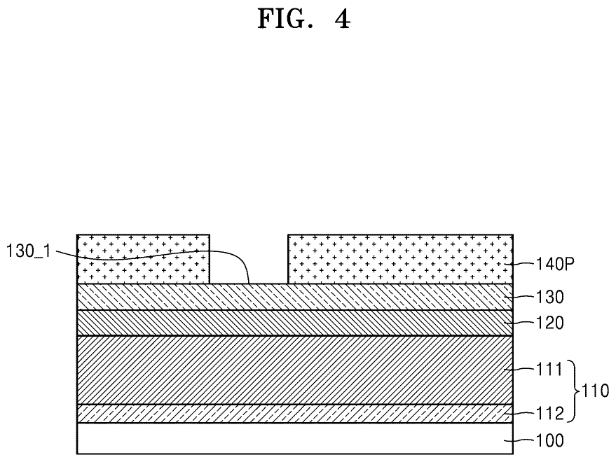

Referring to FIGS. 1 and 4 together, an operation of forming a first photoresist pattern 140P by patterning the first photoresist film 140 may be performed in block S130.

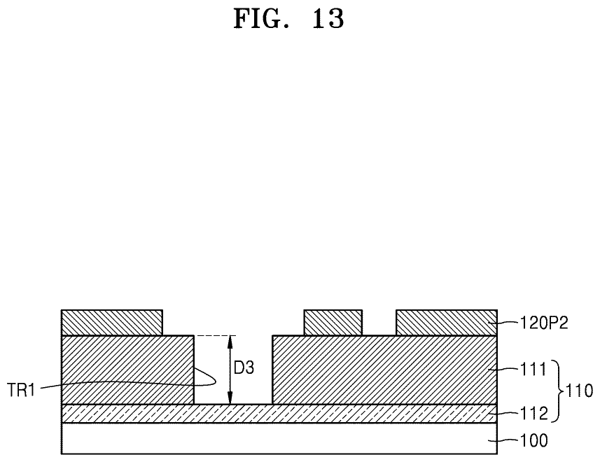

As illustrated in FIG. 4, the first photoresist pattern 140P may expose a first region 130_1 of the insulating film 130. In some embodiments, the first region 130_1 of the insulating film 130 may overlap (e.g., in a vertical direction) a first trench TR1 (refer to FIG. 13) to be formed through subsequent processes. For example, the first photoresist pattern 140P may expose a region where the first trench TR1 will be formed later.

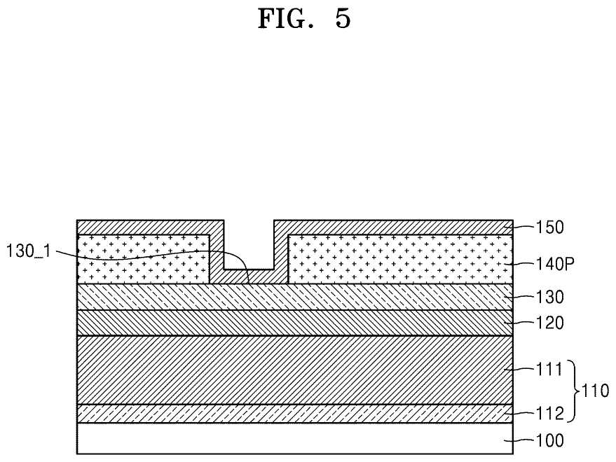

Referring to FIGS. 1 and 5 together, an operation of forming a protective film 150 covering the first photoresist pattern 140P and the insulating film 130 may be performed in block S140.

As illustrated in FIG. 5, the protective film 150 is formed on (e.g., formed directly thereon) upper and lateral side surfaces of the first photoresist pattern 140P and on the first region 130_1 of the insulating film 130 exposed by the first photoresist pattern 140P. For example, in an embodiment the first photoresist pattern 140P may be completely covered by the protective film 150. For example, the first photoresist pattern 140P may not be exposed. In some embodiments, the protective film 150 may include an oxide film. For example, in an embodiment the protective film 150 may include silicon oxide and/or another oxide. However, embodiments of the present disclosure are not necessarily limited thereto.

In some embodiments, the forming of the protective film 150 in block S140 may use an atomic layer deposition (ALD) process. By the ALD process, the protective film 150 may be formed on the upper and lateral side surfaces of the first photoresist pattern 140P and the first region 130_1 of the insulating film 130 exposed by the first photoresist pattern 140P. For example, as the protective film 150 is formed using the ALD process, the first photoresist pattern 140P may be completely covered.

In some embodiments, the protective film 150 may have a thickness in a range of about 100 nm or less. For example, in an embodiment the protective film 150 may have a thickness in a range of about 50 nm to about 100 nm. Alternatively, in an embodiment, the protective film 150 may have a thickness in a range of about 50 nm or less. For example, in an embodiment the protective film 150 may have a thickness in a range of about 5 nm to about 25 nm.

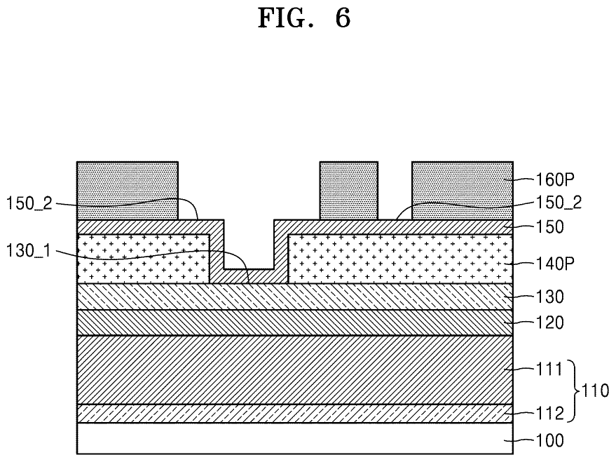

Referring to FIGS. 1 and 6, an operation of forming a second photoresist pattern 160P may be performed in block S150.

As illustrated in FIG. 6, the second photoresist pattern 160P may be formed in a state that the protective film 150 covers the first photoresist pattern 140P. For example, in some embodiments, in the forming of the second photoresist pattern 160P, the second photoresist pattern 160P may be spaced apart from the first photoresist pattern 140P (e.g., in a vertical direction) with the protective film 150 disposed therebetween.

In some embodiments, the protective film 150 may protect the first photoresist pattern 140P in the forming of the second photoresist pattern 160P. For example, in an embodiment the second photoresist pattern 160P may be formed through a process of exposing a portion of the second photoresist film and removing the portion thereof. The protective film 150 may cover the first photoresist pattern 140P when the process of forming the second photoresist pattern 160P is performed so that the protective film 150 may prevent the first photoresist pattern 140P from being removed or damaged by a solution that may be used in the process of forming the second photoresist film and/or the process of removing the portion of the second photoresist film (e.g., patterning the second photoresist film).

In some embodiments, the second photoresist pattern 160P may be formed using a light source having a different wavelength from that of the first photoresist pattern 140P. For example, in an embodiment the first photoresist pattern 140P may be formed by exposing the first photoresist film 140 to an ArF light source, whereas the second photoresist pattern 160P may be formed by exposing the second photoresist film 140 to a KrF light source. For example, in an embodiment the first photoresist pattern 140P for forming a pattern with a narrower pitch may use an ArF light source, whereas the second photoresist pattern 160P for forming a pattern with a wider pitch may use a KrF light source. In an embodiment in which the first photoresist pattern 140P and the second photoresist pattern 160P may be formed using different light sources, the first and second photoresist patterns 140P and 160P may not react to other light sources during the process of forming each photoresist pattern. In an embodiment in which the first photoresist pattern 140P and the second photoresist pattern 160P are formed using different light sources, the cost may be reduced as compared to an embodiment in which the same type of light source is used.

However, embodiments of the present disclosure are not necessarily limited thereto. For example, in some embodiments, the first photoresist pattern 140P and the second photoresist pattern 160P may be formed using the same type of light source. For example, in an embodiment both the first photoresist pattern 140P and the second photoresist pattern 160P may use an ArF light source. For example, both the first photoresist pattern 140P and the second photoresist pattern 160P may use a KrF light source.

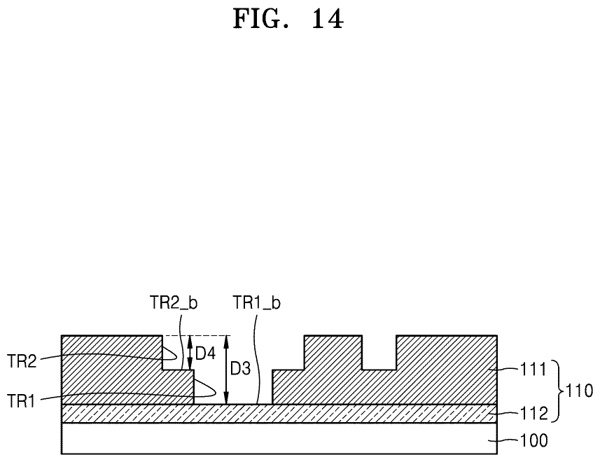

In some embodiments, the second photoresist pattern 160P may expose a second region 150_2 of the protective film 150. The second region 150_2 of the protective film 150 may include a portion of the protective film 150 formed on the first region 130_1 of the insulating film 130. The second region 150_2 of the protective film 150 may directly cover the first photoresist pattern 140P. In some embodiments, the second region 150_2 of the protective film 150 may overlap a second trench TR2 (FIG. 14) to be formed through subsequent processes. For example, the second photoresist pattern 160P may expose a region where the second trench TR2 will be formed later.

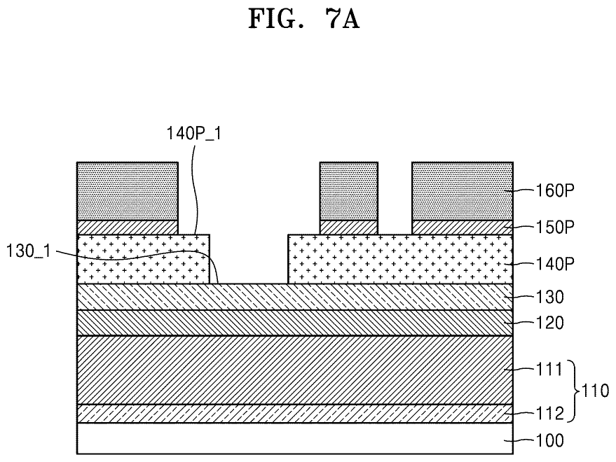

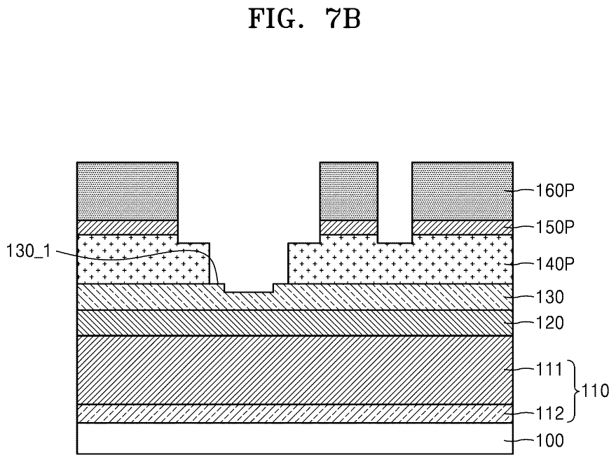

Referring to FIGS. 1, 7A, and 7B, an operation of forming a protective film pattern 150P using the second photoresist pattern 160P may be performed in block S151. For example, the second region 150_2 of the protective film 150 may be etched using the second photoresist pattern 160P. In an embodiment, the process of etching the second region 150_2 of the protective film 150 may be performed by using a wet etch process or a dry etch process.

In an embodiment as illustrated in FIG. 7A, the second region 150_2 of the protective film 150 may be etched using a wet etching process. In an embodiment, while the second region 150_2 of the protective film 150 is removed during the wet etching process, the first photoresist pattern 140P and the insulating film 130 under the protective film 150 may not be removed. In an embodiment, the first photoresist pattern 140P and the insulating film 130 may have an etch selectivity with respect to the protective film 150 in the wet etching process.

Through the above process, a first region 140P_1 of the first photoresist pattern 140P and the first region 130_1 of the insulating film 130 may be exposed.

Alternatively, in an embodiment as illustrated in FIG. 7B, the second region 150_2 of the passivation film 150 may be etched using a dry etching process. During the performance of the dry etching process, while the second region 150_2 of the protective film 150 is removed, the first photoresist pattern 140P under the protective film 150 and a portion of the insulating film 130 may also be removed. Through the above process, a partial region of the first photoresist pattern 140P and the first region 130_1 of the insulating film 130 may be exposed.

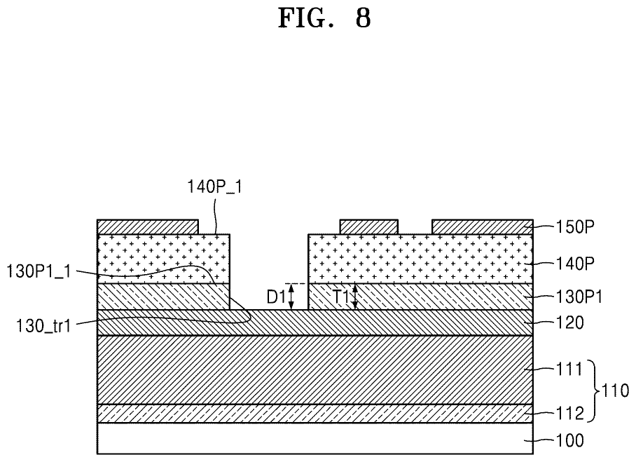

Referring to FIGS. 1 and 8, an operation of forming a first middle trench 130_tr1 using the first photoresist pattern 140P may be performed in block S152.

For example, the first middle trench 130_tr1 may be formed by transferring the first photoresist pattern 140P. Through the above process, a first insulating film pattern 130P1 including the first middle trench 130_tr1 may be formed.

In some embodiments, the forming of the first middle trench 130_tr1 may include completely removing the first region 130_1 of the insulating film 130. Accordingly, in an embodiment a depth D1 of the first middle trench 130_tr1 may be equal to a first thickness T1 of the first insulating film pattern 130P1. A partial region of the hard mask film 120 may be exposed by the first insulating film pattern 130P1. In an embodiment, the second photoresist pattern 160P may then be removed.

However, embodiments of the present disclosure are not necessarily limited thereto. For example, in some embodiments, the second photoresist pattern 160P may be first removed, and then the forming of the first middle trench 130_tr1 using the first photoresist pattern 140P in block S152 may be performed.

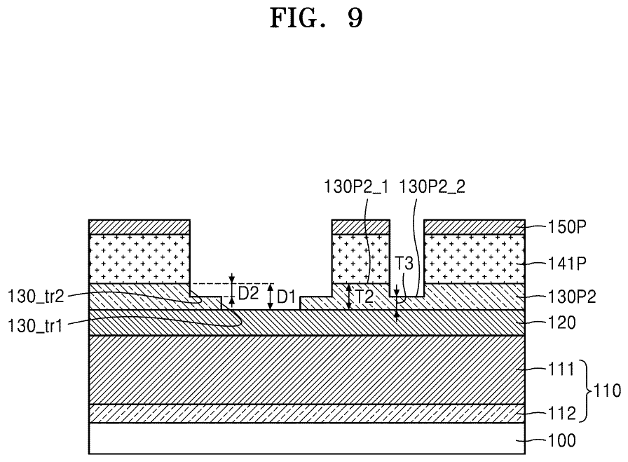

Referring to FIGS. 1 and 9, an operation of forming a third photoresist pattern 141P by etching the first photoresist pattern 140P exposed by the protective film pattern 150P may be performed in block S153.

In an embodiment, the first region 140P_1 of the first photoresist pattern 140P exposed by the protective film pattern 150P may be etched. The third photoresist pattern 141P formed by removing the first region 140P_1 of the first photoresist pattern 140P may be obtained by transferring the protective film pattern 150P. The first region 130P1_1 of the first insulating film pattern 130P1 may be exposed by the third photoresist pattern 141P.

In an embodiment, an operation of forming a second middle trench 130_tr2 using the third photoresist pattern 141P may then be performed in block S154.

In an embodiment, the first region 130P1_1 of the first insulating film pattern 130P1 exposed by the third photoresist pattern 141P may be etched. Accordingly, the second middle trench 130_tr2 may be formed by transferring the third photoresist pattern 141P. Through the above process, a second insulating film pattern 130P2 including the first middle trench 130_tr1 and the second middle trench 130_tr2 may be formed.

In some embodiments, the etching of the first region 130P1_1 of the first insulating film pattern 130P1 using the third photoresist pattern 141P may include not completely removing the first region 130P1_1 of the first insulating film pattern 130P1. Therefore, in an embodiment a depth D2 of the second middle trench 130_tr2 may be less than the first thickness T1 of the first insulating film pattern 130P1. For example, the depth D2 of the second middle trench 130_tr2 may be less than the depth D1 (FIG. 8) of the first middle trench 130_tr1.

In some embodiments, the second insulating film pattern 130P2 may include a first portion 130P2_1 having a second thickness T2 and a second portion 130P2_2 having a third thickness T3. For example, in an embodiment the first portion 130P2_1 may be a portion overlapping the third photoresist pattern 141P (e.g., in a vertical direction). For example, the second portion 130P2_2 may not overlap the third photoresist pattern 141P. In an embodiment, the second thickness T2 of the first portion 130P2_1 of the second insulating film pattern 130P2 may be the same as the first thickness T1 (see FIG. 8) of the first insulating film pattern 130P1 (see FIG. 8). The second thickness T2 of the first portion 130P2_1 of the second insulating film pattern 130P2 may be greater than the third thickness T3 of the second portion 130P2_2. In some embodiments, the second thickness T2 of the first portion 130P2_1 of the second insulating film pattern 130P2 may be the same as the depth D1 of the first middle trench 130_tr1. In some embodiments, a sum of the third thickness T3 of the second portion 130P2_2 of the second insulating film pattern 130P2 and the depth D2 of the second middle trench 130_tr2 is the second insulating film pattern 130P2 may be the same as the second thickness T2 of the first part 130P2_1.

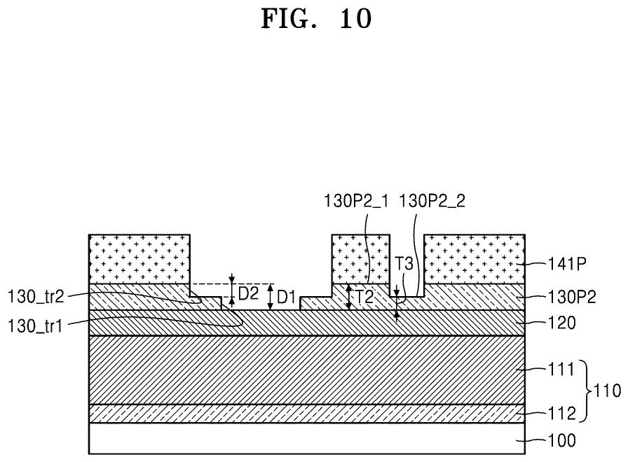

Referring to FIGS. 1 and 10, the protective film pattern 150P may then be removed.

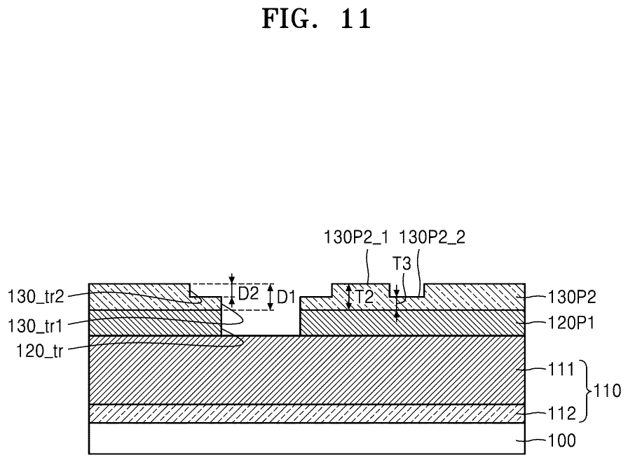

Referring to FIGS. 1 and 11, the third photoresist pattern 141P is removed, and then, an operation of forming a first hard mask pattern 120P1 by etching the hard mask film 120 exposed by the first middle trench 130_tr1 may be performed in block S155. A partial region of the etch target film 110 may be exposed by the first hard mask pattern 120P1. For example, in an embodiment a partial region of the first etch target film 111 may be exposed by the first hard mask pattern 120P1.

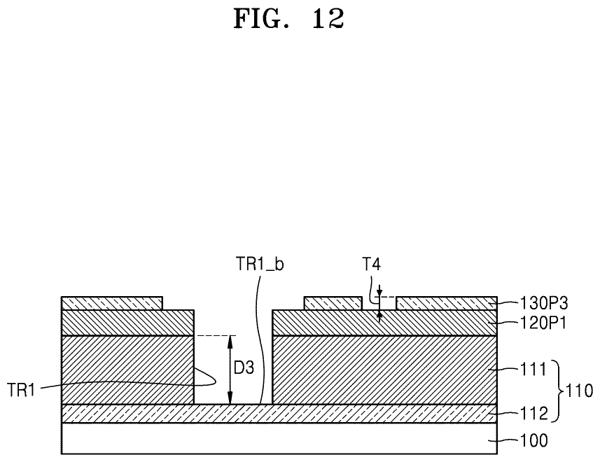

Referring to FIGS. 1 and 12, an operation of forming a first trench TR1 by etching the first etch target film 111 exposed by the first hard mask pattern 120P1 may be performed in block S160. For example, in an embodiment the first etch target film 111 exposed by the first hard mask pattern 120P1 may be completely removed. Accordingly, the second etch target film 112 under the first etch target film 111 may be exposed. In some embodiments, a depth D3 of the first trench TR1 may be the same as a vertical thickness of the first etch target film 111. In the specification, the depth D3 of the first trench TR1 may denote a distance from a lower surface TR1_b of the first trench TR1 to an upper surface of the first etch target film 111 (e.g., in a vertical direction).

At the same time the first trench TR1 is formed by etching the first etch target film 111 in block S160, a third insulating film pattern 130P3 may be formed by etching a portion of the second insulating film pattern 130P2. A partial region of the first hard mask pattern 120P1 may be exposed by the third insulating film pattern 130P3. While portions of the first etch target film 111 and the second insulating film pattern 130P2 are removed to form the first trench TR1, the exposed partial region of the first hard mask pattern 120P1 may not be removed.

In an embodiment, a portion of the first portion 130P2_1 of the second insulating film pattern 130P2 having the second thickness T2 may be removed. For example, in an embodiment the second portion 130P2_2 of the second insulating film pattern 130P2 having the third thickness T3 may be completely removed. As described above, the third thickness T3 of the second portion 130P2_2 of the second insulating film pattern 130P2 may be less than the second thickness T2 of the first portion 130P2_1 of the second insulating film pattern 130P2, and accordingly, while the second portion 130P2_2 of the second insulating film pattern 130P2 is completely removed, the first portion 130P2_1 may not be completely removed. In an embodiment, a process of partially etching the second insulating film pattern 130P2 may be finished after the second portion 130P2_2 of the second insulating film pattern 130P2 is completely removed and before the first portion 130P2_1 is completely removed. Accordingly, a third insulating film pattern 130P3 having a fourth thickness T4 may be formed. In an embodiment, the fourth thickness T4 of the third insulating film pattern 130P3 may be less than or equal to the third thickness T3 of the second portion 130P2_2 of the second insulating film pattern 130P2.

In some embodiments, the forming of the first trench TR1 in block S160 and the forming of the third insulating film pattern 130P3 may be sequentially performed. For example, in an embodiment the forming of the third insulating film pattern 130P3 may be performed after the forming of the first trench TR1 is performed in block S160. For example, the forming of the first trench TR1 may be performed in block S160 after the forming of the third insulating film pattern 130P3 is performed.

Referring to FIGS. 1, 13, and 14, an operation of forming a second trench TR2 by etching the first etch target film 111 exposed by the second hard mask pattern 120P2 may be performed in block S170.

For example, in an embodiment as illustrated in FIG. 13, the second hard mask pattern 120P2 may be formed by using the third insulating film pattern 130P3 as an etching mask. For example, in an embodiment the second hard mask pattern 120P2 may be formed by etching a partial region of the first hard mask pattern 120P1 exposed by the third insulating film pattern 130P3. A portion of the first etch target film 111 may be exposed by the second hard mask pattern 120P2. In an embodiment, the third insulating film pattern 130P3 may then be removed.

As illustrated in FIG. 14, the second trench TR2 may then be formed using the second hard mask pattern 120P2 as an etching mask. For example, in an embodiment the second hard mask pattern 120P2 may be formed by removing a portion of the first etch target film 111 exposed by the second hard mask pattern 120P2.

In some embodiments, a portion of the first etch target film 111 exposed by the second hard mask pattern 120P2 may not be completely removed. For example, before the second etch target film 112 under the corresponding portion is exposed by completely removing the portion of the first etch target film 111 exposed by the second hard mask pattern 120P2, the etching process may be finished. In some embodiments, the second etch target film 112 may not be exposed. In some embodiments, a depth D4 of the second trench TR2 may be less than the depth D3 of the first trench TR1. In the specification, the depth D4 of the second trench TR2 may denote a distance from a lower surface TR2_b of the second trench TR2 to an upper surface of the first etch target film 111 (e.g., in a vertical direction). For example, in some embodiments, a vertical level of the lower surface TR2_b of the second trench TR2 may be less than a vertical level of the lower surface TR1_b of the first trench TR1.

In some embodiments, the first trench TR1 may overlap the second trench TR2 (e.g., in a vertical direction). In some embodiments, a horizontal width of the second trench TR2 may be greater than that of the first trench TR1. In some embodiments, the second trench TR2 may include a portion overlapping the first trench TR1.

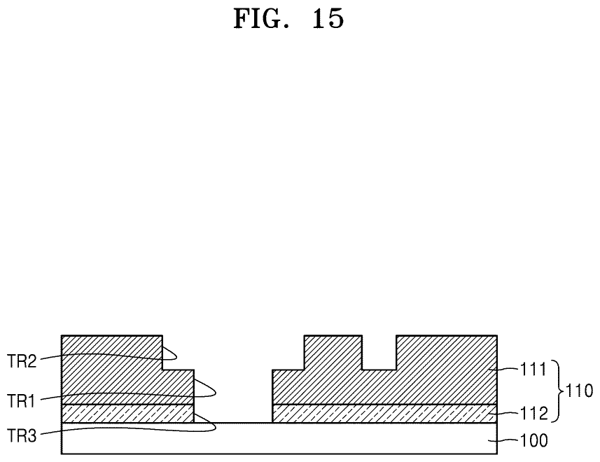

Referring to FIG. 15, the second etch target film 112 may be etched. For example, a third trench TR3 may be formed by etching the second etch target film 112 exposed by the first trench TR1. In some embodiments, the first trench TR1 and the third trench TR3 may be integrated. In some embodiments, the first trench TR1 and the third trench TR3 may integrally constitute a via trench. In some embodiments, the second trench TR2 may constitute a line trench.

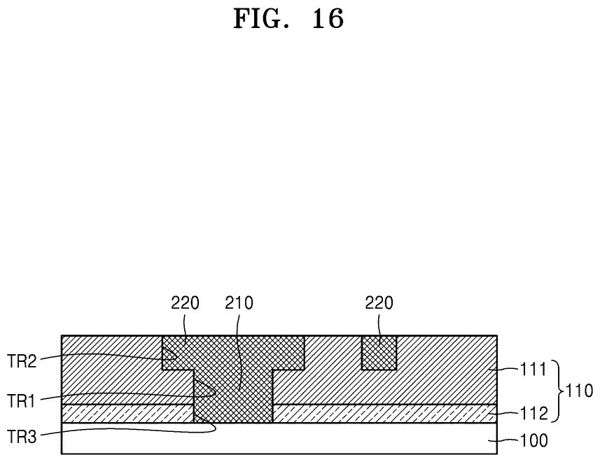

Referring to FIG. 16, a conductive via and a conductive line may be formed by filling the first trench TR1, the second trench TR2, and the third trench TR3 with a conductive material. For example, in an embodiment a conductive via 210 may be formed by filling the first trench TR1 and the third trench TR3 with a conductive material. In an embodiment, a conductive line 220 may be formed by filling the second trench TR2 with a conductive material. In some embodiments, the conductive line 220 may be formed after the conductive via 210 is formed.

However, embodiments of the present disclosure are not necessarily limited thereto. For example, in some embodiments, the forming of the conductive via 210 and the forming of the conductive line 220 may be simultaneously performed.

According to an embodiment of the present disclosure described with reference to FIGS. 1 to 16, a method of manufacturing a semiconductor device with a reduced number of process operations may be provided in block S100. According to the method of manufacturing a semiconductor device in block S100 according to an embodiment of the present disclosure, the number of deposition and etching processes may be reduced.

For example, if the method of manufacturing a semiconductor device in block S100 according to an embodiment of the present disclosure is not used, after forming the first trench TR1 by etching a plurality of insulating films, a hard mask film, and a first etch target film 111 using the first photoresist pattern 140P, and then, the operation of forming the second trench TR2 may be performed through etching another plurality of insulating films, another hard mask film, and the first etch target film 111 using the second photoresist pattern 160P. However, according to the method of manufacturing a semiconductor device in block S100 according to an embodiment of the present disclosure, after forming the first photoresist pattern 140P and the second photoresist pattern 160P overlapping the first photoresist pattern 140P, the first trench TR1 and the second trench TR2 may be formed by etching an insulating film, a hard mask film, and the first etch target film 111. For example, a process of depositing an insulating film and a hard mask film may be reduced. Thus, a process of etching the insulating film, the hard mask film, and the first etch target film 111 may be reduced.

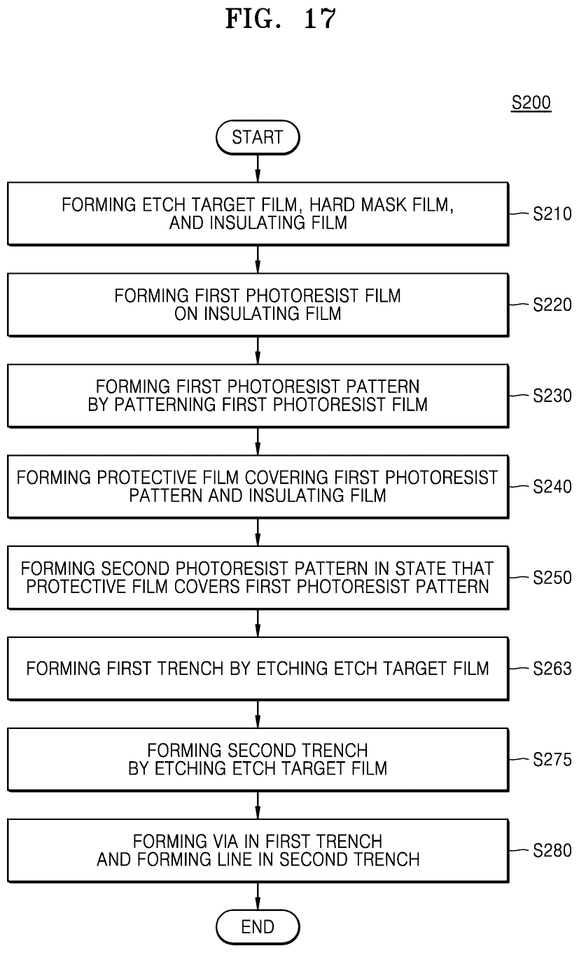

FIGS. 17 to 19 are flowcharts illustrating a method of manufacturing a semiconductor device, according to embodiments (S200).

Referring to FIG. 17, operations of forming an etch target film, a hard mask film, and an insulating film in block S210, forming a first photoresist film on the insulating film in block S220, forming a first photoresist pattern by patterning the first photoresist film in block S230, forming a protective film covering the first photoresist pattern and the insulating film in block S240, and forming a second photoresist pattern in a state that the protective film covers the first photoresist pattern in block S250 may be performed. Descriptions about the forming of an etch target film, a hard mask film, and an insulating film in block S210 to the forming of a second photoresist pattern in block S250 in a state that the protective film covers the first photoresist pattern may refer to the description given with reference to embodiments shown in FIGS. 1 and 2 to 6 for the forming of the etch target film, the hard mask film, and the insulating film in block S110 to the forming of a second photoresist pattern in block S150 in a state that the protective film covers the first photoresist pattern.

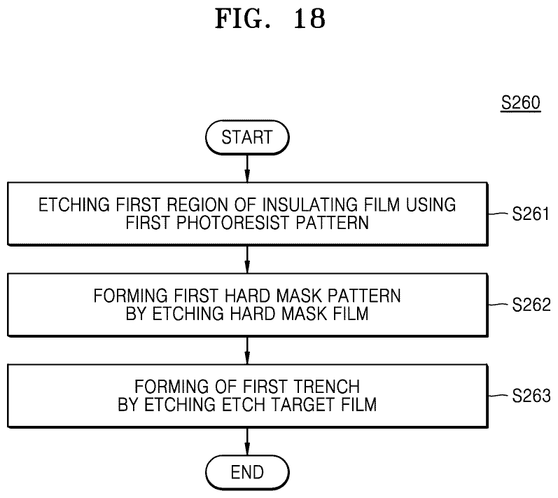

In an embodiment, an operation of forming a first trench by etching the etch target film may then be performed in block S263. Hereinafter, the forming of the first trench by etching the etch target film in block S263 will be described with reference to FIG. 18.

Referring to FIG. 18, the forming of the first trench using a first photoresist pattern may be performed in block S260. In an embodiment, the forming of the first trench using the first photoresist pattern in block S260 may include etching a first region of an insulating film using the first photoresist pattern in block S261, forming a first hard mask pattern by etching the hard mask film in block S262, and forming a first trench by etching the etch target film in block S263. For example, the forming of the first trench by etching the etch target film in block S263 may use the first photoresist pattern as an etching mask.

In some embodiments, before the forming of the first trench by etching the etch target film in block S263, the etching of the first region of the insulating film using the first photoresist pattern in block S261 and the forming of the first hard mask pattern by etching the hard mask film in block S262 may be performed.

In some embodiments, the forming of the first trench using the first photoresist pattern in block S260 may refer to the description given with reference to embodiments shown in FIGS. 1, 8, 11, and 12. For example, each of the etching of the first region of the insulating film using the first photoresist pattern in block S261, the forming of the first hard mask pattern by etching the hard mask film in block S262, and the forming of the first trench by etching the etch target film may be similar to the forming of the first middle trench using the first photoresist pattern of FIG. 1 in block S152, the forming of the first hard mask pattern by etching the hard mask film exposed by the first middle trench in block S155, and the forming of the first trench by etching the etch target film exposed by the first hard mask pattern in block S160.

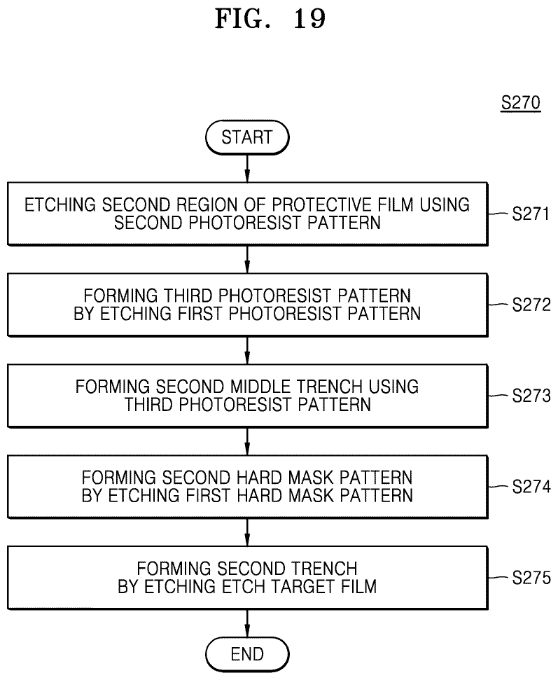

Referring back to FIG. 17, after the forming of the first trench by etching the etch target film in block S263 is performed, an operation of forming a second trench by etching the etch target film may be performed in block S275. Hereinafter, an operation of forming a second trench by etching the etch target film in block S275 will be described with reference to FIG. 19.

Referring to FIG. 19, the process of forming the second trench using a second photoresist pattern may be performed in block S270. In an embodiment, the forming of the second trench using the second photoresist pattern in block S270 may include etching a second region of the protective film using a second photoresist pattern in block S271, forming a third photoresist pattern by etching the first photoresist pattern in block S272, forming a second middle trench using the third photoresist pattern in block S273, forming a second hard mask pattern by etching the first hard mask pattern in block S274, and forming a second trench by etching the etch target film in block S275. For example, the forming of the second trench by etching the etch target film in block S275 may use the second photoresist pattern as an etching mask.

In some embodiments, before forming the second trench by etching the etch target film in block S275, operations of etching the second region of the protective film using the second photoresist pattern in block S271 to forming a second hard mask pattern by etching the first hard mask pattern in block S274 may be performed.

In some embodiments, the forming of the second trench using the second photoresist pattern in block S270 may refer to the description given with reference to embodiments shown in FIGS. 1, 7A, 7B, 9, and 14. For example, the etching of the second region of the protective film using the second photoresist pattern in block S271, the forming of the third photoresist pattern by etching the first photoresist pattern in block S272, the forming of the second middle trench by using the third photoresist pattern in block S273, and the forming of the second trench by etching the etch target film in block S275 may respectively be similar to the forming a protective film pattern using the second photoresist pattern of FIG. 1, the forming of the third photoresist pattern by etching the first photoresist pattern exposed by the protective film pattern in block S153, the forming of the second middle trench using the third photoresist pattern in block S154, and the forming of the second trench by etching the etch target film exposed by the hard mask pattern in block S170.

In some embodiments, before forming the first trench by etching the etch target film in block S263, some operations of forming the second trench using the second photoresist pattern may be performed in block S270. For example, in an embodiment before forming the first trench by etching the etch target film in block S263, the etching of the second region of the protective film using a second photoresist pattern in block S271, the forming of the third photoresist pattern by etching the first photoresist pattern in block S272, and the forming of the second middle trench using the third photoresist pattern in block S273 may be performed.

In some embodiments, after some operations of forming the first trench using the first photoresist pattern are performed in block S260, some operations of forming the second trench using the second photoresist pattern may be performed in block S270, and some operations of forming the first trench using the first photoresist pattern may be subsequently performed. For example, in an embodiment after etching the first region of the insulating film using the first photoresist pattern in block S261, the forming of the third photoresist pattern by etching the first photoresist pattern in block S272 and the forming of the second middle trench using the third photoresist pattern in block S273 may be performed, and subsequently, the forming of the first hard mask pattern by etching the hard mask film in block S262 may be performed.

Referring to FIG. 17, after the second trench is formed by etching the etch target film in block S275, a via in the first trench and forming a line in the second trench may be formed in block S280.

In an embodiment, the forming of a via in the first trench and the forming of a line in the second trench in block S280 may refer to the description given with reference to embodiments shown in FIGS. 1 and 16 for forming a conductive via in the first trench and forming a conductive line in the second trench in block S180.

While the present disclosure has been particularly shown and described with reference to non-limiting embodiments thereof, it will be understood that various changes in form and details may be made therein without departing from the spirit and scope of the present disclosure.

What is claimed is:

1. A method of manufacturing a semiconductor device, the method comprising:
sequentially forming an etch target film and an insulating film on a substrate;
forming a first photoresist film on the insulating film;
forming a first photoresist pattern exposing a first region of the insulating film by patterning the first photoresist film;
forming a protective film covering the first photoresist pattern and the first region of the insulating film;
forming a second photoresist pattern exposing a second region of the protective film, wherein the protective film covers the first photoresist pattern during the forming of the second photoresist pattern;
forming a first trench by etching the etch target film using the first photoresist pattern; and
forming a second trench by etching the etch target film using the second photoresist pattern,
wherein the forming of the first trench is performed after the forming of the second photoresist pattern.

2. The method of claim 1, wherein,
in the forming of the second photoresist pattern, the second photoresist pattern is spaced apart from the first photoresist pattern with the protective film disposed therebetween.

3. The method of claim 1, wherein the forming of the protective film includes forming the protective film on upper and lateral side surfaces of the first photoresist pattern.

4. The method of claim 1, wherein:
the first trench overlaps the first region of the insulating film; and
the second trench overlaps the second region of the protective film.

5. The method of claim 1, wherein the first trench overlaps the second trench.

6. The method of claim 1, wherein a horizontal width of the second trench is greater than a horizontal width of the first trench.

7. The method of claim 1, wherein a vertical level of a lower surface of the first trench is less than a vertical level of a lower surface of the second trench.

8. The method of claim 1, wherein:
the forming of the first photoresist pattern includes exposing a partial region of the first photoresist film to first light; and
the forming of the second photoresist pattern includes exposing a partial region of the second photoresist film to second light,
wherein the first light and the second light have different wavelengths from each other.

9. A method of manufacturing a semiconductor device, the method comprising:
sequentially forming an etch target film, a hard mask film, and an insulating film on a substrate;
forming a first photoresist film on the insulating film;
forming a first photoresist pattern exposing a first region of the insulating film by patterning the first photoresist film;
forming a protective film covering the first photoresist pattern and the first region of the insulating film;
forming a second photoresist pattern exposing a second region of the protective film, wherein the protective film covers the first photoresist pattern during the forming of the second photoresist pattern;
forming a first trench by etching the etch target film using the first photoresist pattern; and
forming a second trench by etching the etch target film using the second photoresist pattern,
wherein, in the forming of the second photoresist pattern, the second photoresist pattern is spaced apart from the first photoresist pattern with the protective film disposed therebetween.

10. The method of claim 9, wherein the forming of the first trench is performed after the forming of the second photoresist pattern.

11. The method of claim 9, wherein the forming of the first trench includes:
etching the first region of the insulating film using the first photoresist pattern;
forming a hard mask pattern by etching a portion of the hard mask film exposed by etching the first region of the insulating film; and
forming the first trench by etching a portion of the etch target film exposed by the hard mask pattern.

12. The method of claim 9, wherein the forming of the second trench includes:
etching the second region of the protective film using the second photoresist pattern;
forming a third photoresist pattern by etching a portion of the first photoresist pattern exposed by the etched protective film;
etching a second region of the insulating film using the third photoresist pattern;
forming a hard mask pattern by etching a portion of the hard mask film exposed by etching the second region of the insulating film; and
forming the second trench by etching a portion of the etch target film exposed by the hard mask pattern.

13. The method of claim 9, wherein:
the hard mask film includes a spin on hardmask (SOH) film; and
the SOH film is in direct contact with the etch target film.

14. The method of claim 9, wherein the first trench overlaps the second trench.

15. The method of claim 9, wherein a horizontal width of the second trench is greater than a horizontal width of the first trench.

16. The method of claim 9, wherein a vertical level of a lower surface of the first trench is less than a vertical level of a lower surface of the second trench.

17. The method of claim 9, further comprising a conductive material filling the first trench and the second trench.

18. A method of manufacturing a semiconductor device, the method comprising:
sequentially forming an etch target film, a hard mask film, and an insulating film on a substrate;
forming a first photoresist film on the insulating film;
forming a first photoresist pattern exposing a first region of the insulating film by patterning the first photoresist film;
forming an oxide film covering the first photoresist pattern and the first region of the insulating film;
forming a second photoresist pattern exposing a second region of the oxide film, wherein the oxide film covers the first photoresist pattern during the forming of the second photoresist pattern;
forming an oxide film pattern by etching the second region of the oxide film using the second photoresist pattern;
forming a first middle trench by etching the first region of the insulating film using the first photoresist pattern;
forming a third photoresist pattern by etching a portion of the first photoresist pattern exposed by the oxide film pattern;
forming a second middle trench having a depth less than a depth of the first middle trench by etching a second region of the insulating film using the third photoresist pattern;
forming a hard mask pattern by etching a portion of the hard mask film exposed by the first middle trench of the insulating film;
forming a via trench by etching a portion of the etch target film exposed by the hard mask pattern; and
forming a line trench by etching portions of the insulating film, the hard mask pattern, and the etch target film that overlap a lower surface of the second middle trench,
wherein the via trench overlaps the line trench, and
the forming of the via trench is performed after the forming of the second photoresist pattern.

19. The method of claim 18, wherein:
a horizontal width of the line trench is greater than a horizontal width of the via trench; and
a vertical level of a lower surface of the via trench is less than a vertical level of a lower surface of the line trench.

20. The method of claim 18, further comprising:
forming a conductive via by filling the via trench with a conductive material; and
forming a conductive line by filling the line trench with a conductive material.
